(19) United States
(12) Patent Application Publication
(10) Pub. No.: US 2004/0119483 A1
(43) Pub. Date: Jun. 24, 2004

(54) Measurement of molten metal with ion conducting phase sensors by means of an electrical measuring unit

(76) Inventors: Gunter Topfer, Wolmirstedt (DE); Rudiger Hartung, Bad Honnef (DE)

Correspondence Address: SMITH MOORE LLP, P.O. BOX 21927, GREENSBORO, NC, 27420, US

(21) Appl. No.: 10/327,211

(22) Filed: Dec. 20, 2002

(51) Int. Cl. G01N 27/62; G01R 27/04; G01R 27/32

(52) U.S. Cl. 324/646

(57) ABSTRACT

The invention is directed to a sensor unit for measuring the concentration of lesser components of a molten bath wherein the sensor unit includes a casing with an interior, an opening for measuring and a connecting area whereby a sensor with a reference electrode is arranged in the interior of the casing and is electrically insulated from the casing and there exist a means of measuring an electric potential between the casing and the sensor. The sensor unit can be used in a measuring unit and used in a method to make refined metals.

The invention relates to a method for producing an ion conducting phase, preferably a β or β″ aluminum oxide type, said ion conducting phase, sensors having said ion conducting phase, a measuring unit including the same, as well as the production of noble metal and the use of the ion conducting phase, sensors and measuring unit.

A series of measuring devices and methods in which said measuring devices are used to qualitatively and preferably quantitatively measure the various components of hot gases and molten baths is known from prior art.

The precise determination of the components of hot gases is of particular importance within the framework of emission control in combustion processes.

In the area of molten baths it is of particular importance to know the exact components of the molten bath and their concentrations, since said components have a direct effect on the material properties and quality of the metals gained from the molten metal and the casting.

Aluminum for instance, as an important lightweight construction material used in the construction of automobiles and in aerospace technology, is subject to increasingly greater requirements with regards to pressure proofing and mechanical/technological qualities. Because of molten aluminum's—tendency to absorb hydrogen, defects in the “gas porosity” are a frequent occurrence in aluminum and aluminum alloys, which considerably impairs the qualities of the casting. The cause of said defects can especially be found in too high hydrogen content of the melt.

Thus a series of methods for quantitatively measuring the hydrogen content in aluminum baths is known from prior art. In this context, the hot extraction analysis, the telegas method, as well as the Hycon probe and aluminum bath probe methods which are based on the “principle of the first bubble” should be mentioned as common methods. Of these methods, only the telegas method offers the possibility of directly measuring the hydrogen content in the bath. However, the telegas method is unsuitable for everyday use in the foundry because of the equipment's sensitivity and susceptibility to disturbances. Another component that affects the quality of the aluminum bath and the resulting casting is sodium.

A possibility of measuring the sodium using an electro-chemical sensor was published in Metallurgical and Materials Transactions 27b, October 1996, pp. 794 799. The disadvantage of using said electro-chemically based sensors is their complex construction and the associated susceptibility in daily use in the foundry.

This also applies to the sensors that are described in the article by W.F. Chu in Technisches Messen [Technical Measuring] 56, 1989.

The tasks are essentially based on the following technical contradictions that are to be solved:

The measuring unit having the sensor is submerged in the molten bath together with the lance that bears it. In in-line measurements the lance and sensor may remain submerged for several hours or even several days, wherein the bath level is above the point where the sensor unit is attached to the lance. For cost reasons, the lance must be at least reusable or fit with different sensors.

When used in the sensor unit, the sensors from the ion conducting phase in accordance with the present invention are exposed to several changes in temperature of up to 1000° C., however according to another task in accordance with the present invention their functionality should not be impaired if the sensor experiences a thermo-mechanical disturbance, in particular, parts of the sensor may not come into contact with and contaminate the bath.

Moreover, the production of ion conducting phases, especially those of the β or β″ aluminum oxide type, preferably for the measurement of sodium in aluminum baths using methods of the prior art are very costly and therefore disadvantageous. The high cost of the methods of the prior art especially results from the multiple grinding, mixing and calcinating steps necessary in the production of an ion conducting phase. Each step must be subjected to a quality control in order to keep fluctuations in quality to a minimum. This is considerably costly in terms of both time and equipment, and is associated with substantial production costs, although there are nevertheless large fluctuations in the quality of the ion conducting phases due to the many manufacturing steps. On the other hand, the fluctuations in the quality of the ion conducting phases obtained using the conventional methods result in sensors that are unsatisfactory in terms of accuracy of measurement. The effect of this inaccuracy in metal processing is that the precision of the concentration measurements is insufficient and has accordingly negative consequences for the quality and properties of the metal material obtained from the molten baths and castings. Until now, these disadvantages could usually only be insufficiently compensated through multiple measurements, parallel measurements and if necessary calibration measurements.

The general task of the present invention is to overcome the disadvantages of the prior art and to contribute to the solution of the following tasks.

### SUMMARY OF THE INVENTION

One task of the present invention is to provide a quickly employable, precise and simple method for measuring the components in molten baths.

Another task of the present invention is to provide a method for producing ion conducting phases that results in fewer fluctuations in the quality of the ion conducting phases as well as lower production costs.

Furthermore, the task of the present invention is that the molten baths and the metals of the castings obtained from the molten baths are subject to fewer variances in terms of their quality and material properties.

In addition, one task of the present invention is to allow the construction of sensor units with very small measurements using the simplest possible construction.

### DETAILED DESCRIPTION OF THE PREFERRED EMBODIMENTS

The tasks of the present invention are solved by methods for producing an ion conducting phase, preferably of an oxidic ceramic type, especially preferred is the β or β″ aluminum oxide type, such as the type from NASICON or LISICON, comprising the following steps:

mixing into a base component mixture of

if necessary a phase stabilizer,

a matrix component that is in excess of the other base components,

a conducting ion component as a base component, by means of

a dispersion agent,

to a dispersion

granulation of the dispersion

molding

sintering

characterized in that the granulating takes place in a whirl-layer-dryer, wherein the formation of the ion conducting phase preferably takes place during the sintering.

The phase stabilizers used in the preferred ion conducting phases of the β or β″ aluminum oxide type in accordance with the present invention are preferably the lithium or magnesium compounds known to the expert, which are can be dissolved or finely dispersed in the dispersion medium. No or only small quantities of the phase stabilizers are required for the phase formation of the β or β″ aluminum oxide phase. Phase mixtures made of the β or β″ aluminum oxide types are also possible by controlling the quantity of phase stabilizers.

For the β or β″ aluminum oxide type, aluminum oxide is preferably used as the matrix component of the ion conducting phase, whereby said aluminum oxide may be replaced by other oxides such as titanium oxide in order to attain stoichiometric defects.

As the conducting ion component of the ion conducting phase, especially for the β or β″ type of aluminum oxide, the expert may choose from known conducting ion components, preferably sodium, potassium, strontium or barium compounds that can be dissolved or finely dispersed in the dispersion agent. Their grain size is preferably smaller or equal to, preferably smaller, than the grain size of the matrix component. If the conducting ion component cannot be brought in directly in accordance with the method of the present invention, especially in the case of proton or lithium ion conductors of the β or β″ aluminum oxide type, their additional synthesis takes place in a processing step known to the expert, through the ion exchange of one of the ion conducting phases in accordance with the present invention through diffusion in the gas phase or in a molten bath with or without the support of an electric field.

It is preferred that the matrix component be used in granule form. In this case, it is preferred that at least 25, preferably at least 50 and especially preferably at least 75% by weight of the matrix component have a particle size in the range from 0.5 to 20, preferably from 1 to 10 and especially preferably from 1 to 5 μm. In addition, it is preferred that the phase stabilizer and the conducting ion component have said grain sizes, both in equal portions. It is especially preferred that the phase stabilizer and the ion conducting component be colloidal, preferably dissolved in the dispersion agent. This can be achieved with a solution agent, preferably a complexing agent such as an alginate, EDTA salt or stearate, if necessary.

The quantitative ratios of the individual basic components in the finished ion conducting phase are usually based on the phase equilibrium, which can be found in the phase diagrams for the individual finished ion conducting phases, at first approximation independent of the exact quantitative ratios of the basic components used. It has therefore proven useful to use at least enough basic component in the method according to the present invention that it corresponds to the stoichiometry of the phase equilibrium of the desired finished ion conducting phase.

The dispersion agents suitable for the method for producing an ion conducting phase in accordance with the present invention are those in which all of the basic components used are only partially soluble. Suitable dispersion agents may be organic or inorganic compounds. Water should especially be named as an example of a suitable inorganic compound.

Moreover, in the method for producing the ion conducting phase in accordance with the present invention, it is advantageous that at least one and preferably all of the following parameters are observed when granulating in the fluidized bed dryer:

p1 air inflow temperature in the range from 50 to 130 preferably from 60 to 100 and especially preferably from 70 to 95° C.,

p2 spray pressure in the range from 1.5 to 3, preferably from 1.7 to 2.5 and especially preferably from 1.8 to 2.1 bar,

p3 spray rate in the range from 50 to 400, preferably from 70 to 300 and especially preferably from 100 to 250 g/min,

p4 air quantity in the range from 100 to 600, preferably 200 to 550 and especially at 250 to 400 m³/h.

Deviations from the parameters may occur as a result of the construction and size of the fluidized bed dryer as well as of other peripheral parameters. Each of the following parameter combinations represents a special implementation of the method in accordance with the present invention: p1p2, p1p2p3, p1p3 and p2p3.

Any customary heatable fluidized bed dryer may be used, although an electrically heated fluidized bed dryer is especially preferred. Such fluidized bed dryers are offered by the company Glatt GmbH in Germany, for instance.

In one implementation of the method in accordance with the present invention, a binder that also positively influences the homogeneity of the pellets is used when granulating in the fluidized bed dryer. The quantity of the binder used lies in the range from 0.01 to 25, preferably from 0.1 to 15 and especially preferably from 1 to 6% by weight, in each case referring to the matrix component. Tri-alcoholamines may be used as binders, especially tri-ethanolamine, and poly-alkyleneglycols, especially poly-ethylenglycol, preferably with a molecular weight in the range from 100 to 500, preferably from 150 to 300 g/Mol, or C₁ to C₅ alkyl-cellulose, preferably methyl cellulose, although alkyl-cellulose is especially preferred.

Furthermore, it is preferred that the pellets contain a residual moisture content of less than 5, preferably less than 4 and especially preferably within the range of 0.1 to 3% by weight in reference to the pellets. At least 20, preferably 50 and especially preferably at least 75% by weight of the pellets have a particle size in the range from 1 to 200, preferably from 20 to 150 and especially preferably from 50 to 120 μm.

Casting preferably takes place by means of pressing the pellets obtained from the granulation into a suitable mold. The pressing may be isostatic or uniaxial. The molding preferably takes place using a pneumatic pressure of less than 2, preferably less than 1 t/cm², in order to obtain a suitable green body during the following sintering process. It is preferred that the pellets be inserted in the mold together with a modeling aid, preferably a plastifier such as a thermoplastic polymer or a wax, as such or in a water emulsion, by means of injection molding or hot molding.

Trialcoholamines, especially triethanolamine and polyalkylene glycol, especially polyethylene glycol, preferably with a molecular weight in the range from 200 to 20000, preferably from 1000 to 10000 g/Mol may likewise be considered as plastifiers. Each modeling aid is used in an amount in the range from 0.1 to 30, preferably from 0.5 to 20 and especially preferably from 1 to 10% by weight of the dry mass, in reference to the pellets.

In the method according to the present invention, the sintering of the green body is preferably the only thermal step during which the ion conducting phase is simultaneously formed. Preferably, the sintering work is carried out in accordance with a certain temperature time frame. This temperature time frame depends on the respective ion conducting phase to be produced. Thus, for example, during the production of the ion conducting phase of the Na-β″ Al₂O₃ type the following temperature time frame is observed for the sintering:

From ambient temperature to 650° C. at 180K/h

From 650 to 850° C. at 30K/h

From 850 to 1050° C. at 180K/h

From 1050 to 1250 at 60K/h

From 1250 to 1600 at 180 K/h

At 1600° C. hold 15′ and cool down to ambient temperature at 600 K/h.

In accordance with the present invention it is preferred that the method for producing the ion conducting phase is carried out without at least one, preferably all of the following steps:

(a) mix grinding of the phase stabilizer and the matrix component into a phase stabilizer/matrix component mixture,

(b) drying of the phase stabilizer/matrix component mixture,

(c) calcination of the dried phase stabilizer/matrix component mixture,

(d) mix grinding of the phase stabilizer/matrix component mixture with the conducting ion component into an ion conducting educt,

(e) calcination of the ion conducting educt into an ion conducting calcine,

(f) granulation of the ion conducting calcine by means of spray drying,

(g) calcination of the base component mixture.

It is preferred that in accordance with the present invention the method is performed without steps (f) or (g), especially without steps (f) and (g). Moreover, it is preferred that in addition to (f) or (g) or (f) and (g), one also abstain from the aforementioned steps and therefore obtain granules with high bulk density and an ion conducting phase, which can be obtained from the granules by means of modeling and sintering with less shrinkage and greater homogeneity. Furthermore, in comparison to conventional methods this can be carried out at a lower sintering temperature. Additionally, the pellets in accordance with the present invention have an improved flow, which is especially advantageous for automatic feeding during the molding process.

Furthermore, the present invention relates to an ion conducting phase that can be obtained by means of the previously described method in accordance with the present invention for producing the ion conducting phase.

The ion conducting phase in accordance with the present invention is provided with preferably at least one, especially preferably all of the following parameters:

1. Gas density in accordance with helium standard leakage rate <10⁻⁵ mbar 1/sec,

2. Electrically non-conducive in accordance with EN 60672 parts I-III,

3. Temperature change resistant at more than 8, preferably at 8 to 20, temperature change constant in accordance with DIN 51068 part II.

Furthermore, the invention relates to a sensor containing the ion conducting phase described above.

Preferably said sensors are comprised of a reference electrode and if necessary a measuring electrode, in the event that it involves a sensor for measuring a gas, and an ion conducting stable electrolyte. It is preferred that (i) the reference electrode includes a, preferably deep, mixture of a combination of (a) titanium dioxide and an alkali metal or alkaline earth metal titanate or (b) tin dioxide and an alkaline metal or alkaline earth metal stannate, whereas the reference electrode preferably is not insulated against the medium to be measured; (ii) during the measurement of a gas the measuring electrode contains a compound that is in thermodynamic equilibrium with the gas to be measured; and (iii) the reference electrode is in contact with the measuring electrode via the ion conducting stable electrolyte. Preferably the ion conducting stable electrolyte consists of at least 5, preferably at least 50 and especially preferably at least 80% by weight of the previously described ion conducting phase. Further details about sensors can be taken from EP 0767 906 B1, whose disclosure represents a part of this application.

The components named in this section can also be obtained by means of the fluidized bed dryer method in accordance with the present invention.

Furthermore, the present invention relates to the use of the ion conducting phase or the above mentioned sensor in order to measure a substance, especially an individual gas or an individual metal in a mixture A of the individual gas and at least one other gas or a mixture B of the individual gas and at least one other metal or a mixture C of the individual metal and at least one other metal. In one embodiment, the ion conducting phase in accordance with the present invention can also be used simultaneously for measuring an individual gas or an individual metal in a combination of at least two of the mixtures A, B and C.

In this context, it is preferred that the individual gas have a share by volume in the range from 0.1*10⁻⁴ up to 20% of the total volume of the mixture A, or the individual gas have a share by volume in the range from 0.1*10⁻⁴ up to 20% of the total volume of the mixture B, or the individual metal have a share by weight in the range from 0.1*10⁻³ up to 20% of the total weight of the mixture C.

During the use of the ion conducting phase in a sensor, it is preferred that the individual gas be selected from the group consisting of H, nitric oxides, carbonic oxides, F, Cl, Br, I, O, or that the individual metal be selected from the group consisting of Na, Li, K, Rb, Cs, Ca, Sr, Ba, Pb, Mn, Fe, Co, Ni, Sn, In, Ga, Bi, Cr, La, Pr, Nd, Sm, Eu, Gd, Tb, Dy, Er, Yb.

With the aid of the ion conducting phase in accordance with the present invention as a component of a sensor, preferably nitrogen compounds with one or two nitrogen and one to five oxygen atoms as nitric oxides can be measured. Said nitric oxides are preferably nitrogen monoxide, nitrous monoxide, nitrous dioxide, nitrous trioxide, nitrogen dioxide, dinitrogen tetroxide, dinitrogen pentoxide, dinitrogen trioxide and dinitrogen hexaoxide. The aforementioned oxides are generally referred to under the term NOₓ.

When measuring gases by means of a sensor used in the ion conducting phase in accordance with the present invention it is preferred that a support electrode be used. This support electrode is preferably a salt consisting of a metal as a cation, which is preferably identical to the conducting ion of the ion conducting phase, and an anion that is a derivative of the gas to be measured. For example, for measuring carbon dioxide a support electrode that is mainly alkali or alkaline earth carbonate, preferably sodium carbonate, is used, whereby in this case the conducting ion in the ion conducting phase is preferably also sodium. When measuring NOₓ, an alkali or alkaline earth nitrate, preferably barium nitrate, is used as the support electrode, whereby in this case the conducting ion in the ion conducting phase is preferably also barium. When measuring the hydrogen concentrations using a sensor with the help of the ion conducting phase in accordance with the present invention, it is recommended that an alkali or alkaline earth hydride be used as the support electrode.

Another preferred embodiment relates to sensors, comprising

in an ion conducting layer with a conducting ion as the first layer

a secondary layer that can form a chemical compound with the conducting ion

with a common phase border to the ion conducting layer characterized in that on the phase border upwards of a temperature of 50° C., preferably within the temperature range in which the sensor is used, a third layer forms as a reference layer.

The chemical compound preferably forms when the conducting ion passes from the ceramic material of the first layer into the secondary layer and in the area of the secondary layer into which it has immigrated there forms a chemical composition that is different from the secondary layer.

The third layer preferably forms in a temperature range from 200 to 1200 and especially preferably from 450 to 950° C. The third layer forms in a time period from 0.01 to 6000, preferably from 0.1 to 1000 and especially preferably from 1 to 600 sec, always measured from the time that a temperature within the temperature range is achieved.

The ion conducting layer preferably contains at least 5, preferably at least 7, and especially preferably at least 8 to 20% by weight (with reference to the ion conducting layer) of a conducting ion component in an ion conducting phase.

It is preferred that the ion conducting layer forms an inorganic phase, in which there may be individual conducting ions involved in this phase, especially the sodium with integers and if applicable non-integer oxidation numbers.

Ceramic materials known to the expert may be used as the ceramic material for the ion conducting layer. Ion conducting phases are preferred, preferably of the B and β″ Al₂O₃ type. The ion conducting phase can especially preferably be achieved by the method in accordance with the present invention.

The secondary layer contains at least 50 and especially preferably at least 90% (always referring to the weight of the secondary layer) of an elemental noble metal and a transitional metal oxide, which can combine with the conducting ion of the ion conducting phase a mixed oxide compound, preferably alkali or alkaline earth titanates, such as sodium or strontium titanate, alkali or alkaline earth zirconate, such as sodium or strontium zirconate or alkali or alkaline earth stannate, such as sodium or strontium stannate. Further details about suitable mixed oxide compounds can be found in EP 0 767 906 A1, which is hereby regarded as a component of this disclosure.

Furthermore, for the purpose of increasing the electrical conductivity, the secondary layer may contain an electron conductor with preferably at least 1% by weight and especially preferably with at least 10% by weight always referring to the secondary layer.

The electron conductor used in the secondary layer is preferably a noble metal, especially preferably gold or platinum or an alloy thereof, as well as graphite.

The metal oxides contained in the secondary layer, preferably transition-metal oxides, are selected from the group of oxides of Ti, Zr, Hf, Fe and W. Of these, TiO₂, Fe₂O₃, SnO₂, ZrO₂ and WO₃ are especially preferred. In addition, it is preferred that the individual transition metal oxides be used individually.

In one embodiment of the sensor, the material of the first layer has been worked into the secondary layer at least in part as a fine powder during the production of the secondary layer in order to increase the contact surface for the formation of the third layer. It has been found that this also improves the reaction of the sensor.

The secondary layer has a thickness in the range from 0.1 to 500, preferably from 10 to 100 and especially preferably from 10 to 50 μm. The reference layer preferably has a thickness in the range from a monomolecular layer up to the thickness of the secondary layer. The secondary layer in accordance with the present invention is preferably producible using thick layer technology. For this, any of the methods known to the expert may be used. Among these, the screenprint method is especially preferred for producing the secondary layer in accordance with the present invention. It is also possible to form the secondary layer as an autonomous body, which is in contact with the first layer as well as the ion conducting phase and forms the reference layer on the contact surface.

In accordance with another embodiment of the present invention, the ion conducting layer is an ion conducting disk carrying the secondary layer on one side. This disk preferably has a thickness that is sufficient for providing the sensor with the suitable stability for its application. Normally, the disk has a thickness of from 0.5 to 10 mm. However, in accordance with the present invention it has been found that it is especially advantageous to avoid a scattering of the specimen that the ion conducting disk have a uniform thickness of at least 3 mm, especially preferably at least 5 mm. The disk may have any surface shape suitable for its use. Usually, the disk is somewhat circular or rectangular in shape, so that one or several secondary layers can be can be attached to it with the necessary spatial separation, without coming into contact with one another.

Furthermore, one embodiment of the sensor in accordance with the present invention is characterized in that the support electrode is arranged opposite the secondary layer on the medium side of the ion conducting disk. This is advantageous for instance when the reference electrode area opposite the medium to be measured, should preferably be shielded against the molten bath.

Moreover, it is advantageous based on another embodiment of the sensor in accordance with the present invention that the ion conducting disk be in contact with a shield on the side of the medium to be measured. This shield can ensure that no tension is created due to the considerable thermal stress of the ion conducting disk, especially on the outside edges, thereby minimizing thermo-mechanical stresses. The shield is preferably made of a temperature change-proof ceramic material, preferably bomitride or graphite, that is suitable for channeling off the thermal energy acting on the ion conducting disk, and/or to distribute said thermal energy over the surface of the ion conducting disk in such a way that the above-mentioned damage resulting from the thermal stress on the ion conducting disk occurs more slowly or not at all. This is especially accomplished when the thermal energy is distributed as evenly as possible over the ion conducting disk. This can be achieved preferably in that the shield is mainly in non-thermal channeling contact with the medium side of the ion conducting disk. Moreover, it is preferred in this context that the shield be shaped like a disk. It is also preferred in this context that the shield be perforated. In this way, in addition to its function, the shield possesses sufficient mechanical stability and the medium can at the same freely, but with little turbulence, reach the area of the ion conducting disk suitable for measuring the components and if necessary the support electrode as well. Moreover, the shield is designed in such a way that a measuring conductor can be attached to it. This is preferably located in the bridges between the perforated areas. The shield can also be used to electrically insulate the one working electrode, which is used in conjunction with the ion conducting disk, against the ion conducting disk.

It has proven advantageous in another embodiment of the sensor in accordance with the present invention that the medium side be shielded from the ion conducting disk by a semi-permeable membrane. The material for this membrane preferably allows gas to pass through in such a way that a head-space forms in the semi-permeable membrane or between it and the ion conducting disk. This is especially advantageous when the sensor is used in liquid media such as molten baths in order to measure the gas concentrations. Moreover, it is preferred that the support electrode is arranged in the head-space between the semi-permeable membrane and the ion conducting disk.

In accordance with another embodiment of the sensor, an ion conducting disk has several secondary layers that are spatially separated from one another and not interconnected. These several secondary layers may be made from the same metal or different metals, preferably Pt or Au, or metal oxides, preferably alkali or alkaline earth titanate or zirkonate, although metal oxides are preferred. The advantage of this construction is that several measurements can be taken simultaneously with one sensor. With identical secondary layers, several comparative measurements for determining the reproducibility of a certain measurement can be taken. If however different secondary layers are applied, different measurements of different dimensions can be taken at the same time. If necessary, the several secondary layers can be paired with suitable support electrodes, so that for instance the concentration of a certain gas and a metal or two different gases or metals can be measured at the same time. In this context, the simultaneous measurement of the concentration of Na and hydrogen in aluminum baths is especially preferred.

In order to ensure the reliable handling of the sensor for measuring components, especially in the foundry, it is advantageous for it to be possible to attach a lance to the sensor. In this context it is especially advantageous that the sensor in the ion conducting disk be provided with a notch, and if necessary the shield in the ion conducting disk as well in order to secure the lance.

In the aforementioned context, the present invention relates to a sensor unit for measuring the concentration of lesser components in a molten bath, comprising a casing with an interior, an opening for measuring and a connecting area, whereby a sensor with a reference electrode is arranged in the interior and said sensor, which is preferably corresponds to the sensor described above in accordance with the present invention, is electrically insulated against the casing. Moreover, the sensor unit is provided with a means of measuring an electric potential between the casing and the sensor. The sensor unit is characterized in that the reference electrode and the opening for measuring are interconnected so as to allow gas to pass through.

In measuring probes of the prior art which have been used up to now to measure the concentrations of the components of an aluminum bath, the reference electrode is shielded in such a way that contact with, for instance, gaseous components of the bath is prevented, since this frequently leads to the failure of the reference electrode. This especially applies to reference electrodes that are at least partially made of sodium. With such reference electrodes, there appear at least large changes in the reference signal that do not ensure an accurate measurement of the concentrations of lesser components of the molten bath. In accordance with the present invention, the reference electrode is preferably designed in such a way that said electrode is on the side of the sensor turned away from the opening for measuring, whereby the sensor is preferably designed to be gas permeable. The sensor thus protects the reference electrode from the bath, while at the same time allowing an exchange of gases between the interior of the casing and the reference electrode situated therein.

With reference to the longevity and the attainment of very precise measuring results, it is especially advantageous that the reference electrode be at least partially designed with an ion conducting phase. This is especially designed as a combination of (a) titanium dioxide and an alkali metal or alkaline earth metal titanate or (b) tin dioxide and an alkali metal or alkaline earth metal stannate in, preferably well mixed mixture, whereby the reference electrode is not preferably insulated against the medium to be measured.

In accordance with another design of the sensor unit, the sensor is at least partially connected to the casing by means of an insulating layer. In this context, it is especially advantageous that the insulating layer and the sensor form a seal in order to prevent the accumulation of molten bath in the interior of the casing. On the one hand this prevents an electrical contact between the sensor and the casing, and on the other hand the components of the sensor unit arranged in the interior and/or downstream modules are protected against thermal overload, corrosion or the like. In order to fix the position of the sensor it is proposed that the casing be provided with a projection, which at least partially extends over the side of the sensor that faces the opening for measurements. When the sensor unit is immersed into the molten bath, the contact area between the molten bath and the sensor can be precisely defined by means of the projection.

In accordance with another embodiment, a casing contact and a sensor contact are arranged in the interior of the casing and electrically insulated from one another. In this context, the connection between the casing contact and the casing and between the sensor contact and the sensor are electrically conductive. The casing contact and the sensor contact are designed in such a way that fluctuations in the manufacturing variations of the components of the sensor unit, different thermal expansion behaviors of these components or movements relative to one another on the basis of different thermal coefficients of expansion can be evened out. In this context, it is especially proposed that the casing contact and/or the sensor contact have elastic or resilient characteristics.

In order to ensure the undisturbed transmission of signals, it must be guaranteed that the casing contact and the sensor contact are always electrically insulated against one another. For this purpose, it is especially proposed that the sensor contact be arranged directly next to the sensor and that the sensor contact preferably be provided with an insulator ring surrounding said sensor contact. The casing contact is annular in shape and provided with a canal, said casing contact being wedged in a notch in the casing. The wedging of the casing contact in a notch in the casing guarantees a close contact with the casing. Said notch and the projection of the casing are preferably designed in such a way that the sensor and the sensor contact are fixed axially and/or radially in the interior of the casing by the positioning of the casing contact. Said canal has a diameter that is larger than the measurements of the sensor contact, so that these are spatially separated from one another, preferably in an essentially coaxial and adjacent arrangement, and are electrically insulated against one another. Such an arrangement saves space and also ensures the functionality of the sensor unit even in extreme thermal and chemical conditions over a long time period.

In accordance with another design, the sensor unit is provided with a shield that surrounds the opening for measuring. The shield is preferably a separate module that is cylindrical in design and is interconnected with the casing. In order to balance the pressure differentials and create calm zones of the molten bath in the area of the measuring position, the shield is provided with flow openings, which are preferably distributed over the entire surface of the shield. These flow openings allow ventilation, for instance when the sensor unit is immersed in the molten bath.

In accordance with another inventive aspect, a measuring unit comprising the sensor unit described above and a lance for the immersion of the sensor unit in a molten bath is proposed, whereby said lance has a connecting section that together with the connecting area of the sensor unit forms a detachable and sealed connection. This modular measuring unit is especially suitable for the use of aluminum baths, whereby the sensor unit is immersed below the surface of the molten bath by means of the lance in order to ensure sufficient measuring reliability, even in industrial use and with falling molten bath levels without having to drive the sensor unit deeper. Since the connection is detachable, the lance can be constructed of expensive and durable materials, while inexpensive expendable materials can be used for the sensor unit, since the latter remains completely submerged in the molten bath, thereby preventing oxidation with the oxygen in the air. This also ensures that no molten material enters the interior of the casing, although there exists an atmospheric balance between the molten bath and the interior of the sensor unit, whereby the reference signal of the reference electrode in accordance with the present invention is independent of the oxygen partial pressure in the aluminum bath. The connection between the lance and the sensor unit may be achieved by means of known connection elements such as a bolted joint, a bayonet joint or a plug and socket connection. Said connecting section is preferably arranged in the interior of the sensor unit in order to prevent the connecting section from coming into contact with molten bath surrounding the casing.

In accordance with another design, it is proposed that the lance be provided with an end piece with a connecting section, which has sealing receptacles for lance contacts, which are arranged in such a way that at least one first lance contact is interconnected with the casing contact and at least one second lance contact is interconnected with the sensor contact. Said end piece is preferably made of a thermo-shock resistant material, preferably of boronitrite. The end piece especially has the function of protecting the prefabricated parts arranged in the interior of the lance against any squirting of the molten bath or the like, in the case that the lance is submerged in the molten bath without a suitably attached sensor unit.

In accordance with another design of the measuring unit, at least the first lance contact or at least the second lance contact consists of an electrically conductive fiber material, preferably containing graphite. It is especially advantageous that said lance contacts and the respective casing or sensor contact have different breaking characteristics, so that movements relative to one another can be offset with the electric contact being lost. This means that touching contact allows a sort of offsetting movement, such as occur as a result of measuring and forming tolerances, thermal expansion, vibrations or the like.

Moreover, a measuring unit is proposed in which at least the first lance contact is interconnected with a casing conductor and at least the second lance contact is interconnected with a sensor conductor. These conductors are preferably linked to a display for electric signals or another electronic modular unit in such a way that the measuring signal can be visually or acoustically evaluated by the user or by means of a computer. If necessary, said display also includes data acquisition tools, which relay the electric signals to certain evaluation units. The display essentially serves to depict the potential between the casing and the sensor, whereby conclusions about the concentration of lesser components of the molten bath can be drawn.

Furthermore, the invention relates to a method for producing noble metal, comprising the following steps:

Measuring a share of at least one component contained in the molten bath in addition to the main metal, with a sensor in accordance with the present invention or a lance in accordance with the present invention for measuring the actual concentration of the component,

Adjusting the share of the component to a desired concentration by increasing or decreasing the share of the component,

Casting the molten bath when the actual and desired concentration are the same.

Since the sensor contained in the measuring unit or sensor unit in accordance with the present invention, and the ion conductor contained in said sensor are exposed to considerable mechanical and thermal as well as corrosive stress when taking measurements in molten baths, it is necessary with regard to obtaining the most accurate measurement possible that the sensors be replaced after a certain time. This is the only way to achieve a high quality and constant homogeneity of the molten bath. The sensor should be replaced preferably at least after every 2, preferably at least after every 5 and especially preferably after every 10 measurements.

The time period over which the sensor can be used for taking measurements in the molten bath depends on various factors. In this context, particular emphasis is to be placed on the type of alloy, on which the corrosive effect of the molten bath especially depends. In accordance with the present invention, a clear definition of the status of the sensor is determined through a combination of the measuring results from a temperature measurement, the measurement of the sensor tension as well as the sensor resistance.

In general, in accordance with the present invention a distinction is made between at least four basic conditions for defining the status of the sensor, based on temperature, voltage and resistance values or processes.

First Status: “New”:

A new sensor whose working electrode has had no contact with the molten bath is being inserted. The sensor voltage lies at approximately 0V with a high level of sensor resistance, which preferably lies above 10000 and especially preferably above 1000 mΩ. The temperature of the sensor is less than that of the molten bath.

Second Status: “Hot”:

The sensor is immersed into the molten bath. The temperature climbs at least up to the temperature of the melt or exceeds it. The sensor voltage continues to rise in a range from 300 to 3000, preferably 500 to 2000 and especially preferably 700 to 1500 mV. The sensor resistance drops compared to the resistance measured in status 1 and preferably lies in the range from 10 to 10000 and especially preferably from 100 to 1000 mΩ.

Third Status: “Cold”:

The sensor has been removed from the molten bath. In comparison to the status “new”, the sensor resistance remains in the range from 10 to 10000 and especially preferably from 100 to 1000 mΩ, due to the solidified aluminum between the sensor and working electrode, whereas the sensor voltage gradually drops below 300, preferably 100 and especially preferably 50 mV and upon further cooling approaches 0V. 0V is reached preferably after at least 1 and especially preferably after at least 10 minutes after the sensor has been removed from the molten bath.

Fourth Status: “Defect”:

Provided the sensor is still in the molten bath, the sensor has at least the temperature of the molten bath. The voltage of the sensor drops below 100, preferably 50 and especially preferably 10 mV.

If the sensor is defective, it is preferred that a unit controlling the measuring stops the measuring process and notifies the operator by means of a display that the sensor needs to be replaced.

The invention also relates to an ennobled metal, obtained by means of method described above as well as the use of this ennobled metal in bars, sheet metals, cables or molded pieces.

### BRIEF DESCRIPTION OF THE DRAWINGS

Preferred embodiments of the present invention are explained in more detail below by means of examples and figures, in which:

FIG. 1 shows a cross section of a measuring unit.

FIG. 2 shows a horizontal outline of one embodiment of the sensor unit.

FIG. 3 shows a flowchart for the course of the measuring process with a sensor in accordance with the present invention and the restriction of the number of measurements.

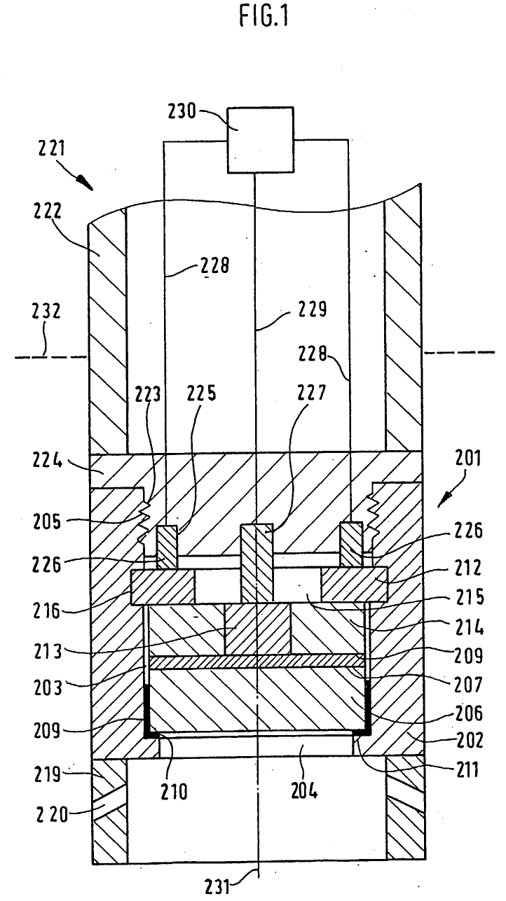

FIG. 1 shows schematically a diagram and cross section of a modular built measuring unit 221, whereby a sensor unit 201 is attached to a lance 222 for immersion in a molten bath. The lance 222 is provided with a connecting section 223, which forms a detachable and sealed connection together with a connecting area 205 of the sensor unit 201. For this purpose, the lance 222 is provided with an end piece 224, which forms a detachable connection with a casing 202 of the sensor unit 201.

The sensor unit 201 for measuring the concentration of lesser components of a molten bath includes the casing 202 with an interior 203, an opening for measuring 204 and a connecting area 205. In the interior 203 there is a sensor 206 with a reference electrode 207, whereby an electrically insulating layer 209 is arranged between the sensor 206 and the casing 202. In this way the sensor 206 is spatially separated from and electrically insulated against the casing, whereby the insulating layer 209 can be implemented as a type of coating or also as a separate component part.

The reference electrode 207 is provided with an ion conducting phase 208, whereby the reference electrode 207 is arranged on the side of the sensor 206 facing away from the opening for measuring 204. In this case the sensor 206 is designed to be gas permeable. The connection between the casing 202, the insulating layer 209 and the sensor 206 is designed as a seal 210, so as to prevent the molten bath from penetrating into the interior 203 of the casing 202. The position of the sensor 206 is fixed by means of a projection 211 of the casing 202. This projection 211 extends at least 2 mm radially inwards and is circular in design. The projection 211 decreases the direct thermo-mechanical stress exactly in the critical peripheral area of the sensor 6.

In the direction of an axis 231 the casing 202 attaches to a cylindrical shield 219 with flow openings 220. When the measuring unit 221 is immersed up to the surface of the molten bath 232, the shield creates a calmed zone 219 in the molten bath so that the measuring signal is not impaired by the movements of the molten bath. Said flow openings serve to ventilate the cavity in the interior of the shield 219 upon immersion in the molten bath.

The measuring unit 221 is also provided with a means for measuring an electric potential between the casing 202 and the sensor 206. To this end, a sensor contact 207 is arranged next to the reference electrode 213 with an annular insulation ring 214 surrounding said sensor contact. The insulation ring 214 serves as an electrical insulation against the casing 202 as well as the neighboring casing contact 212. The annular casing contact 212 is lodged in a notch 216 of the casing 202, thereby ensuring close contact with the casing 202 and an axial fixation of the sensor 206, the sensor contact 213 and the casing contact 212.

The end piece 224 is provided with sealing receptacles 225 for lance contacts 226, 227, whereby said receptacles 225 are arranged in such a way that a first lance contact 226 is interconnected with the casing contact 212 and at least a second lance contact 227 is interconnected with the sensor contact 213. Said second lance contact 227 extends through a canal 215 of the annular casing contact 212. The first lance contact 226 and the casing contact 212 as well as the second lance contact 227 and the sensor contact 213 are each designed to have different breaking qualities, so that any relevant movement of the lance contacts 226, 227 against the casing contact 212 or the sensor contact 213 is secured. Said contacts are preferably made of an electrically conductive fiber material, especially one containing graphite, preferably designed in such a way that the largest possible contact surface is produced regarding their cross sections. The first lance contact 226 is connected via a casing conductor 228 and the second lance contact 227 is connected via sensor conductor 229 to a display 230 for electric signals.

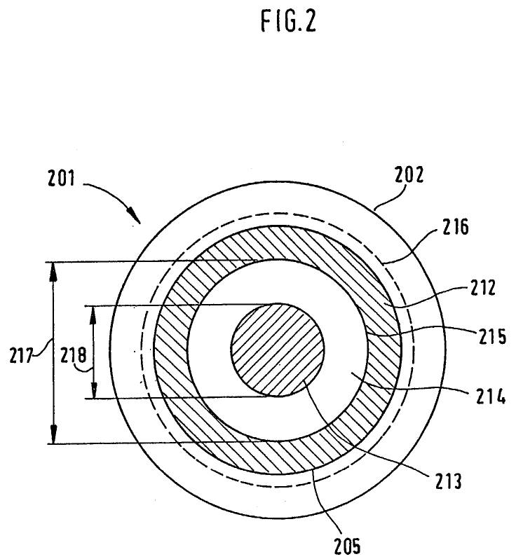

FIG. 2 shows a top view of the design of the sensor unit 201 in accordance with the present invention. The outline shows a coaxial arrangement of the sensor contact 213 and the casing contact 212. Both contacts are arranged in the interior 203 (not shown) of the casing 202, which is secured via its connecting area 205 to the end piece (not shown) of the lance (not shown). The order of said contacts corresponds to the manner shown in FIG. 1.

The annular casing contact 212 is fixed in a notch 216 of the casing 202, whereby a part of the insulating ring 214 and the sensor contact 213 can be seen through the canal 215 of the casing contact 212. In order to ensure the functionality of the sensor unit 201, the sensor contact 213 and the casing contact 212 are electrically insulated against one another. From the drawing it can be seen that the canal 215 has a diameter 217 that is larger than distance 218 from the sensor contact 213, so that when these are arranged coaxially and adjacent to one another they are spatially separated and electrically insulated from one another. With reference to the arrangement of the second lance contact 227 (not shown), it should also be taken into account that said second lance contact has dimensions that are smaller than the diameter 217 of the canal 215, since after all these extend through and into the canal 215.

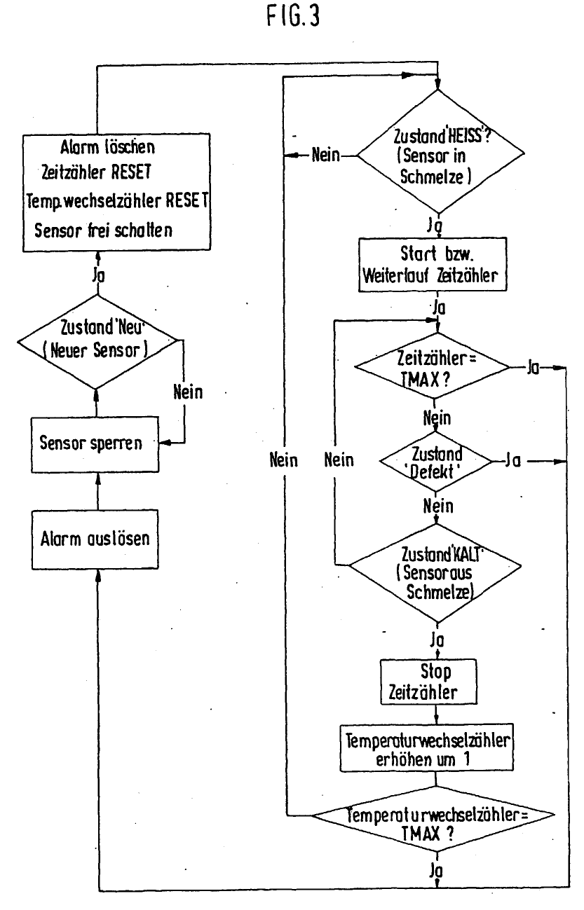

In FIG. 3 it is first inquired whether a new sensor is being used, which would correspond to the status “new”. If this is the case, the time meter for the duration of the measurement and the thermoshock meter are set to zero. When the sensor is used or old, the sensor is disabled and the time meter and thermoshock meter are set to the value that corresponds to the condition of the sensor. This can be controlled by a data processing unit, in which the signal from the sensor is read for instance via a bar code. Then the status “hot” is inquired, which is set when the sensor is immersed in the molten bath. If “hot” status is reached, the time meter is switched on or continued. If the time meter has reached a value “TMAX” for the maximum allowable life of a certain sensor, this is signaled to the user, for instance by an alarm, and the sensor is disabled from further measurements. If “TMAX” is not reached, it is checked whether the sensor is defective and is therefore in the “defect” status. If this is the case, the sensor is disabled from further measurements, for instance via an alarm. If the sensor is not defective, the measurement can be taken. When the sensor is removed from the molten bath once the measurement is complete, the sensor cools off, so that the “cold” status is reached. Once the “cold” status is reached, the time meter is stopped and the thermoshock meter continues to count to a unit that corresponds to the number of measurements. If it is now determined that either the specified maximum allowable number of measurements in accordance with the thermoshock meter is reached and/or the specified maximum allowable measuring time in accordance with the time meter and therefore the maximum allowable life “TMAX” is reached, the sensor is disabled, for instance via an alarm. Otherwise, further measurements can be taken with this sensor, in that another measurement is continued with the inquiry about the status “hot”. The data necessary for the status of the respective sensor are stored in the data processing unit.

### EXAMPLE

For drying in a fluidized bed dryer of the type GPCG from the company Glatt GmbH (Germany), for producing a Na-β″ aluminum oxide ion conducting phase with 90.13% by weight, Al₂O₃ as aluminum oxide powder AES 11 of the Somitomo KK as a matrix component, 0.77% by weight Li₂O as lithium hydroxide monohydrate from the company Merk AG as a stabilizer component as well as a sodium hydroxide solution from the company Merk AG for 9.1% by weight N₂O as an ion conducting component is finely dispersed in deionized water by means of an Utraturax and sprayed as a dispersion into the fluidized bed dryer at an air inflow temperature of 90° C., an air quantity of 400 m³/h, a spraying rate of 75 g/min and a spraying pressure of 2 bar. In a yield of 82%, a basic material was obtained, which is pressed into a green body, for instance in accordance with the method known from EP 0 767 906 B 1, and then sintered into the Na-β″ aluminum oxide ion conducting phase.

1. A sensor unit for measuring the concentration of lesser components of a molten bath comprising a casing with an interior, an opening for measuring and a connecting area, whereby a sensor with a reference electrode is arranged in the interior and is electrically insulated against the casing, and a means of measuring an electric potential between the casing and the sensor, characterized in that the reference electrode and the opening for measuring are interconnected in such a way that gas is allowed to pass through.

2. The sensor unit of claim 1 wherein the reference electrode is arranged on a side of the sensor facing away from the opening for measuring, and the sensor is gas permeable.

3. The sensor unit of claim 1 wherein the sensor partially includes an ion conducting phase.

4. The sensor unit of claim 1 wherein the sensor is interconnected with the casing by means of an insulating layer.

5. The sensor unit of claim 4 wherein the insulating layer and the sensor form a seal to prevent an accumulation of molten bath in the interior of the casing.

6. The sensor unit of claim 1 wherein the casing is provided with a projection that fixes the position of the sensor and at least partially extends over the side of the sensor facing the opening for measuring.

7. The sensor unit of claim 1 where in the interior of the casing, a casing contact and a sensor contact are arranged in such a way that they are electrically insulated against one another, whereby there is an electrically conductive connection between the casing contact and the casing, and an electrically conductive connection between the sensor contact and the sensor.

8. The sensor unit of claim 7 wherein the sensor contact is arranged directly next to the sensor and the sensor contact is provided with a surrounding insulation ring.

9. The sensor unit of claim 7 wherein the casing contact is annular with a canal and is lodged in a notch of the casing.

10. The sensor unit of claim 9 wherein the canal has a diameter that is larger than dimensions measurements of the sensor contact such that they are spatially separated from and electrically insulated against each other.

11. The sensor unit of claim 1 wherein the opening for measuring is surrounded by a cylindrical shield that has flow openings.

12. A measuring unit including a sensor unit for measuring the concentration of lesser components of a molten bath comprising a casing with an interior, an opening for measuring and a connecting area, whereby a sensor with a reference electrode is arranged in the interior and is electrically insulated against the casing, and a means of measuring an electric potential between the casing and the sensor, characterized in that the reference electrode and the opening for measuring are interconnected in such a way that gas is allowed to pass through; and a lance for immersing the sensor unit in a molten bath, characterized in that the lance is provided with a connecting section, which together with the connecting area of the sensor unit forms a detachable and sealed connection.

13. The measuring unit of claim 12 wherein the lance is provided with an end piece containing a nitride and the connecting section has sealing receptacles for at least two lance contacts, wherein the lance contacts are arranged such that one first lance contact is interconnected with the casing contact and that second lance contact is interconnected with the sensor contact.

14. The measuring unit in accordance with claim 12 wherein the first lance contact or the second lance contact is comprised of an electrically conductive fibber material.

15. The measuring unit of claim 12 wherein the lance contacts and the respective casing contact and the respective sensor contact have different breaking qualities, so that movements relative to one another can be offset without breaking the electric contact.

16 The measuring unit of claim 12 wherein the first lance contact is interconnected with a casing conductor and the second lance contact is interconnected with a sensor conductor which are interconnected with a display for electric signals.

17. A method for producing a refined metal by means of a molten bath, comprising the following steps:
a) measuring a share of one component contained in the molten bath in addition to the refined metal by means of a sensor comprising a casing with an interior, an opening for measuring and a connecting area, whereby a sensor with a reference electrode is arranged in the interior and is electrically insulated against the casing, and a means of measuring an electric potential between the casing and the sensor, characterized in that the reference electrode and the opening for measuring are interconnected in such a way that gas is allowed to pass through;
b) adjusting the share of the component to a desired concentration by increasing or decreasing the share of the component; and
c) casting the molten bath when the actual and desired concentrations are the same.

18. A noble metal produced by a method comprising the steps of a) measuring a share of one component contained in the molten bath in addition to the refined metal by means of a sensor comprising a casing with an interior, an opening for measuring and a connecting area, whereby a sensor with a reference electrode is arranged in the interior and is electrically insulated against the casing, and a means of measuring an electric potential between the casing and the sensor, characterized in that the reference electrode and the opening for measuring are interconnected in such a way that gas is allowed to pass through;
b) adjusting the share of the component to a desired concentration by increasing or decreasing the share of the component; and
c) casting the molten bath when the actual and desired concentrations are the same.

19. Articles of manufacturing consisting of bars, sheet metals, cables, molded pieces oraerospace products comprising the nobel metal of claim 18.
